(19) United States
(12) Patent Application Publication
(10) Pub. No.: US 2022/0406850 A1
(43) Pub. Date: Dec. 22, 2022

(54) PHOTODETECTOR ELEMENT AND IMAGE SENSOR

(71) Applicant: FUJIFILM Corporation, Tokyo (JP)

(72) Inventors: Masashi ONO, Shizuoka (JP); Hirotaka SATOU, Shizuoka (JP); Toshihiro ISE, Shizuoka (JP)

(73) Assignee: FUJIFILM Corporation, Tokyo (JP)

(21) Appl. No.: 17/884,532

(22) Filed: Aug. 9, 2022

Related U.S. Application Data
(63) Continuation of application No. PCT/JP2021/004478, filed on Feb. 8, 2021.

(30) Foreign Application Priority Data
Feb. 13, 2020 (JP) 2020-022577

(51) Int. Cl. H01L 27/30; H01L 51/44; H01L 51/42; C09K 11/66; C09K 11/06

(52) U.S. Cl. CPC H01L 27/307; H01L 51/441; H01L 51/4273; C09K 11/661; C09K 11/06; C09K 2211/1011; C09K 2211/1014; H01L 2251/301

(57) ABSTRACT

There is provided a photodetector element including a first electrode layer; a second electrode layer; a photoelectric conversion layer provided between the first electrode layer and the second electrode layer; an electron transport layer provided between the first electrode layer and the photoelectric conversion layer; and a hole transport layer provided between the photoelectric conversion layer and the second electrode layer, in which the photoelectric conversion layer contains an aggregate of semiconductor quantum dots that contain a metal atom and contains a ligand coordinated to the semiconductor quantum dot, the hole transport layer contains an organic semiconductor, and the second electrode layer is formed of a metal material containing at least one metal atom selected from Au, Pt, Ir, Pd, Cu, Pb, Sn, Zn, Ti, W, Mo, Ta, Ge, Ni, Cr, or In. There is also provided an image sensor including the photodetector element.

### CROSS-REFERENCE TO RELATED APPLICATIONS

This application is a Continuation of PCT International Application No. PCT/JP2021/004478 filed on Feb. 8, 2021, which claims priority under 35 U.S.C § 119(a) to Japanese Patent Application No. 2020-022577 filed on Feb. 13, 2020. Each of the above application(s) is hereby expressly incorporated by reference, in its entirety, into the present application.

### BACKGROUND OF THE INVENTION

### 1. Field of the Invention

The present invention relates to a photodetector element having a photoelectric conversion layer that contains semiconductor quantum dots and an image sensor.

### 2. Description of the Related Art

In recent years, attention has been focused on photodetector elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetector element that is used in an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth for achieving a high quantum efficiency, and thus it has not been widespread.

By the way, in recent years, research on semiconductor quantum dots has been advanced. Jae Woong Lee, Do Young Kim, and Franky So, “Unraveling the Gain Mechanism in High Performance Solution-Processed PbS Infrared PIN Photodiodes”, Advanced Functional Materials 25, 1233-1238 (2015) discloses a photodiode using indium-tin oxide as a cathode electrode, ZnO as an electron transport layer, a PbS quantum dot as a photoelectric conversion layer, 1,1-bis[(di-4-tolylamino)phenyl]cyclohexane as a hole transport layer, MoO₃ as a hole injection layer, and Ag as an anode electrode.

### SUMMARY OF THE INVENTION

In recent years, with the demand for performance improvement of an image sensor and the like, further improvement of various characteristics that are required in a photodetector element used in the image sensor and the like is also required. For example, it is required to further reduce the dark current of the photodetector element. In a case where the dark current of the photodetector element is reduced, a higher signal-to-noise ratio (SN ratio) can be obtained in the image sensor.

According to the study of the inventors of the present invention, it was found that the photodetector element having a photoelectric conversion layer formed of semiconductor quantum dots tended to have a relatively high dark current, and there was room for reducing the dark current.

Further, as a result of studies on the photodiode disclosed in Jae Woong Lee, Do Young Kim, and Franky So, “Unraveling the Gain Mechanism in High Performance Solution-Processed PbS Infrared PIN Photodiodes”, Advanced Functional Materials 25, 1233-1238 (2015), the inventors of the present invention found that the dark current is high. Here, the dark current is a current that flows in a case of not being irradiated with light.

An object of the present invention is to provide a photodetector element in which the external quantum efficiency is high and the dark current is reduced, and an image sensor.

As a result of diligent studies on a photodetector element having a photoelectric conversion layer containing semiconductor quantum dots, the inventors of the present invention found that in a case where a photoelectric conversion layer containing an aggregate of semiconductor quantum dots that contain a metal atom and containing a ligand that is coordinated to the semiconductor quantum dots is used as a photoelectric conversion layer, a hole transport layer containing an organic semiconductor material is laminated on the photoelectric conversion layer, and an electrode composed of a metal material containing at least one metal atom selected from Au, Pt, Ir, Pd, Cu, Pb, Sn, Zn, Ti, W, Mo, Ta, Ge, Ni, Cr, or In is used as an electrode on the hole transport layer side, the photodetector element can have a high external quantum efficiency and a reduced dark current, and have completed the present invention.

<1> A photodetector element comprising:

a first electrode layer;

a second electrode layer;

a photoelectric conversion layer provided between the first electrode layer and the second electrode layer;

an electron transport layer provided between the first electrode layer and the photoelectric conversion layer; and

a hole transport layer provided between the photoelectric conversion layer and the second electrode layer,

in which the photoelectric conversion layer contains an aggregate of semiconductor quantum dots that contain a metal atom and contains a ligand coordinated to the semiconductor quantum dot,

the hole transport layer contains an organic semiconductor, and

the second electrode layer is formed of a metal material containing at least one metal atom selected from Au, Pt, Ir, Pd, Cu, Pb, Sn, Zn, Ti, W, Mo, Ta, Ge, Ni, Cr, or In.

<2> The photodetector element according to <1>, in which a content of an Ag atom in the second electrode layer is 98% by mass or less.

<3> The photodetector element according to <1> or <2>, in which the second electrode layer is formed of a metal material containing at least one metal atom selected from Au, Pd, Ir, or Pt.

<4> The photodetector element according to any one of <1> to <3>, in which a work function of the second electrode layer is 4.6 eV or more.

<5> The photodetector element according to any one of <1> to <4>, in which the organic semiconductor contained in the hole transport layer is a compound represented by any of Formulae 1-1 to 1-6,

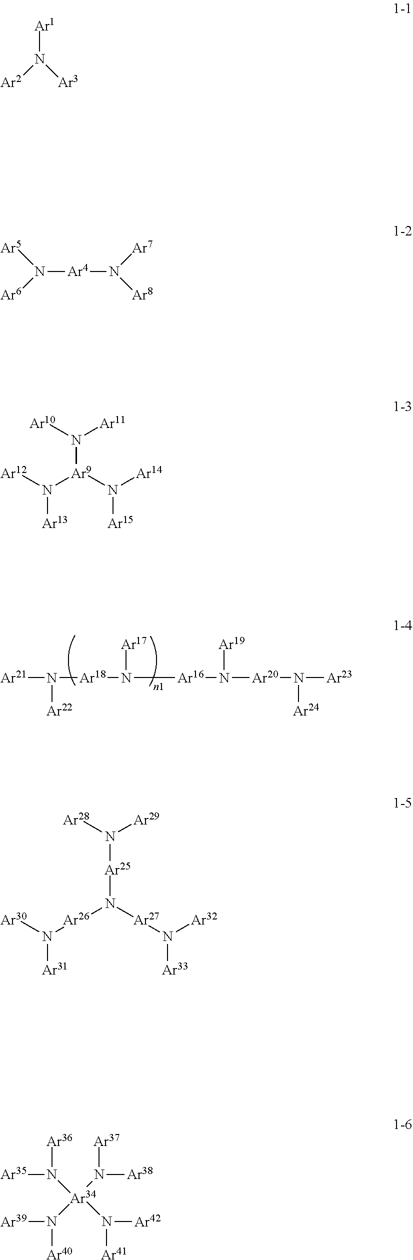

in Formula 1-1, Ar¹ to Ar³ each independently represent an aromatic hydrocarbon group which may have a substituent or an aromatic heterocyclic group which may have a substituent;

in Formula 1-2, Ar⁴ represents a divalent linking group containing an aromatic hydrocarbon group which may have a substituent or an aromatic heterocyclic group which may have a substituent, and Ar⁵ to Ar⁸ each independently represent an aromatic hydrocarbon group which may have a substituent or an aromatic heterocyclic group which may have a substituent;

in Formula 1-3, Ar⁹ to Ar¹⁵ each independently represent an aromatic hydrocarbon group which may have a substituent or an aromatic heterocyclic group which may have a substituent;

in Formula 1-4, Ar¹⁶ to Ar²⁴ each independently represent an aromatic hydrocarbon group which may have a substituent or an aromatic heterocyclic group which may have a substituent, and n1 represents an integer of 0 to 10;

in Formula 1-5, Ar²⁵ to Ar³³ each independently represent an aromatic hydrocarbon group which may have a substituent or an aromatic heterocyclic group which may have a substituent;

in Formula 1-6, Ar³⁴ to Ar⁴² each independently represent an aromatic hydrocarbon group which may have a substituent or an aromatic heterocyclic group which may have a substituent.

<6> The photodetector element according to <5>,

in which at least one of Ar¹ to Ar³ of Formula 1-1 has an electron donating group,

at least one of Ar⁴ to Ar⁸ of Formula 1-2 has an electron donating group,

at least one of Ar⁹ to Ar¹⁵ of Formula 1-3 has an electron donating group,

at least one of Ar¹⁶ to Ar²⁴ of Formula 1-4 has an electron donating group,

at least one of Ar²⁵ to Ar³³ of Formula 1-5 has an electron donating group, and

at least one of Ar³⁴ to Ar⁴² of Formula 1-6 has an electron donating group.

<7> The photodetector element according to <6>, in which the electron donating group is an alkyl group, an alkenyl group, an alkynyl group, an aryl group, a heterocyclic group, an alkoxy group, an aryloxy group, an alkylthio group, an amino group, a hydroxy group, or a silyl group.

<8> The photodetector element according to any one of <1> to <7>, in which the organic semiconductor contained in the hole transport layer is a compound represented by Formula 3-1 or 3-2,

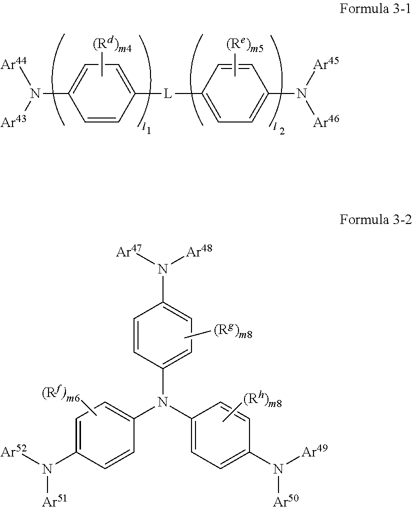

in Formula 3-1, Ar⁴³ to Ar⁴⁶ each independently represent an aromatic heterocyclic group which may have a substituent, a group represented by Formula 3-a, or a group represented by Formula 3-b,

R^{d} and R^{e} each independently represent a substituent,

m⁴ and m⁵ each independently represent an integer of 0 to 4,

I₁ and I₂ each independently represent 1 or 2, and

L represents a single bond or a divalent linking group;

in Formula 3-2, Ar⁴⁷ to Ar⁵² each independently represent an aromatic heterocyclic group which may have a substituent, a group represented by Formula 3-a, or a group represented by Formula 3-b,

R^{f} to R^{h} each independently represent a substituent, and

m6 to m8 each independently represent an integer of 0 to 4;

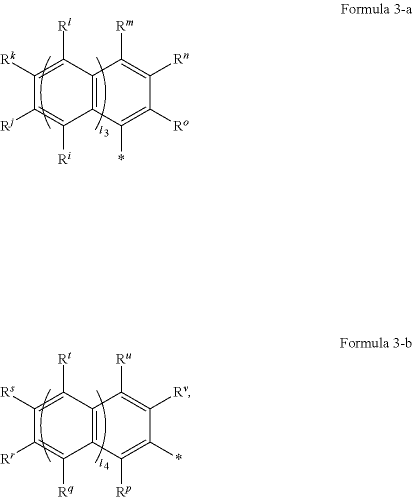

in Formula 3-a, Rⁱ to R^{o} each independently represent a hydrogen atom or a substituent, I₃ represents 0 or 1, and * represents a bonding site;

in Formula 3-b, R^{p} to R^{v} each independently represent a hydrogen atom or a substituent, I₄ represents 0 or 1, and * represents a bonding site.

<9> The photodetector element according to <8>, in which at least one of Ar⁴³ to Ar⁴⁶ of Formula 3-1 has an electron donating group, and

at least one of Ar⁴⁷ to Ar⁵² of Formula 3-2 has an electron donating group.

<10> The photodetector element according to any one of <1> to <9>, in which the semiconductor quantum dot contains a Pb atom.

<11> The photodetector element according to any one of <1> to <10>, in which the semiconductor quantum dot contains PbS.

<12> The photodetector element according to any one of <1> to <11>, in which the ligand contains at least one selected from a ligand containing a halogen atom or a polydentate ligand containing two or more coordination moieties.

<13> The photodetector element according to <12>, in which the ligand containing a halogen atom is an inorganic halide.

<14> The photodetector element according to <13>, in which the inorganic halide contains a Zn atom.

<15> The photodetector element according to any one of <1> to <14>, in which the photodetector element is a photodiode-type photodetector element.

<16> An image sensor comprising the photodetector element according to any one of <1> to <15>.

<17> The image sensor according to <16>, in which the image sensor is an infrared image sensor.

According to the present invention, it is possible to provide a photodetector element in which the external quantum efficiency is high and the dark current is reduced, and an image sensor.

### BRIEF DESCRIPTION OF THE DRAWINGS

FIG. 1 is a view illustrating an embodiment of a photodetector element.

### DESCRIPTION OF THE PREFERRED EMBODIMENTS

Hereinafter, the contents of the present invention will be described in detail.

In the present specification, “to” is used to mean that numerical values described before and after “to” are included as a lower limit value and an upper limit value, respectively.

In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

<Photodetector Element>

The photodetector element according to the embodiment of the present invention is characterized by the following facts:

the photodetector element includes a first electrode layer;

a second electrode layer;

a photoelectric conversion layer provided between the first electrode layer and the second electrode layer;

an electron transport layer provided between the first electrode layer and the photoelectric conversion layer; and

a hole transport layer provided between the photoelectric conversion layer and the second electrode layer,

in which the photoelectric conversion layer contains an aggregate of semiconductor quantum dots that contain a metal atom and contains a ligand coordinated to the semiconductor quantum dot,

the hole transport layer contains an organic semiconductor, and

the second electrode layer is formed of a metal material containing at least one metal atom selected from Au, Pt, Ir, Pd, Cu, Pb, Sn, Zn, Ti, W, Mo, Ta, Ge, Ni, Cr, or In.

According to the present invention, it is possible to obtain a photodetector element having a high external quantum efficiency and having a low dark current.

In a case where a semiconductor quantum dot that contains a Pb atom is used as the semiconductor quantum dot in the photoelectric conversion layer, in the photoelectric conversion layer, the ratio of the number of Pb atoms having a valence of 1 or less to the number of Pb atoms having a valence of 2 (the number of Pb atoms having a valence of 1 or less/the number Pb atoms having a valence of 2) is preferably 0.20 or less, more preferably 0.10 or less, and still more preferably 0.05 or less. According to this aspect, it is possible to obtain a photodetector element in which the dark current is still further reduced.

The details of the reason why such effects are obtained are unknown; however, it is presumed to be due to the following points. Examples of the Pb atom having a valence of 2 include a Pb atom bonded (coordinated) to a ligand, a Pb atom bonded to a chalcogen atom, and a Pb atom bonded to a halogen atom. Examples of the Pb atom having a valence of 1 or less include a metallic Pb atom and a Pb atom in the dangling bond state. Here, the amount of free electrons in the photoelectric conversion layer is conceived to be correlated with the dark current, and it is presumed that the dark current can be reduced by reducing the amount of free electrons. It is conceived that the Pb atom having a valence of 1 or less in the photoelectric conversion layer plays a role of an electron donor, and it is presumed that the amount of free electrons in the photoelectric conversion layer can be reduced by reducing the ratio of the Pb atom having a valence of 1 or less. For this reason, it is presumed that the dark current of the photodetector element can be further reduced.

In the present specification, the value of the ratio of the number of Pb atoms having a valence of 1 or less to the number of Pb atoms having a valence of 2 in the photoelectric conversion layer is a value measured by X-ray photoelectron spectroscopy using an X-ray photoelectron spectroscopy (XPS) apparatus. Specifically, an XPS spectrum of the Pb4f (7/2) orbital of the photoelectric conversion layer is subjected to the curve fitting by the least squares method to carry out the waveform separation into a waveform W1 of which the intensity peak is present in a range of a bond energy of 137.8 to 138.2 eV and a waveform W2 of which the intensity peak is present in a range of a bond energy of 136.5 to 137 eV. Then, the ratio of a peak surface area S2 of the waveform W2 to the peak surface area S1 of the waveform W1 is calculated, and this value is taken as the ratio of the number of Pb atoms having a valence of 1 or less to the number of Pb atoms having a valence of 2 for the photoelectric conversion layer. Here, in the measurement by X-ray photoelectron spectroscopy, the bond energy of the intensity peak may fluctuate slightly depending on the reference sample. In the semiconductor quantum dot in the present invention, a Pb—X bond between the Pb atom and an anion atom X paired with the Pb atom, where the Pb—X bond has a valence of 2, is present. Therefore, the contribution from Pb—X or a bond having an intensity peak at the same position of the bond energy as Pb—X is combinedly added to obtain the above-described peak surface area S1. Then, the contribution from a bond having an intensity peak at a position where the bond energy is lower than that is defined as the peak surface area S2. For example, as the ratio of the number of Pb atoms having a valence of 1 or less to the number of Pb atoms having a valence of 2 in the photoelectric conversion layer, it is possible to use a value calculated by using a waveform of which the intensity peak is present at a bond energy of 138 eV as the waveform W1, and by using a waveform of which the intensity peak is present at a bond energy of 136.8 eV as the waveform W2.

Examples of the means by which the ratio of the number of Pb atoms having a valence of 1 or less to the number of Pb atoms having a valence of 2 in the photoelectric conversion layer is set to be 0.20 or less include a method of bringing the photoelectric conversion layer into contact with an aprotic solvent to carry out rinsing at the time of manufacturing a semiconductor film or drying the photoelectric conversion layer in an atmosphere of an oxygen-containing gas.

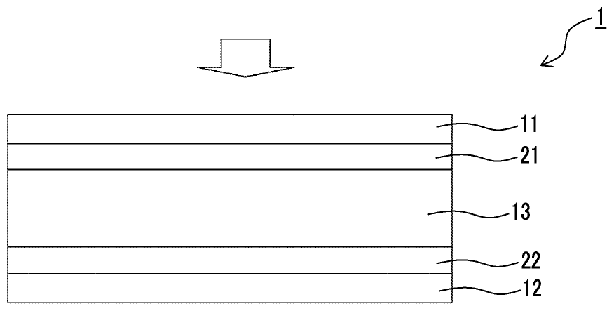

Hereinafter, the details of the photodetector element of the present invention will be described with reference to FIG. 1. FIG. 1 is a view illustrating an embodiment of a photodiode-type photodetector element. It is noted that an arrow in the FIGURE represents the incidence ray on the photodetector element. A photodetector element 1 illustrated in FIG. 1 includes a second electrode layer 12, a first electrode layer 11 opposite to the second electrode layer 12, a photoelectric conversion layer 13 provided between the second electrode layer 12 and the first electrode layer 11, an electron transport layer 21 provided between the first electrode layer 11 and the photoelectric conversion layer 13, and a hole transport layer 22 provided between the second electrode layer 12 and the photoelectric conversion layer 13. The photodetector element 1 illustrated in FIG. 1 is used by causing light to be incident from above the upper electrode 11. Although not illustrated in the drawing, a transparent substrate may be arranged on the surface of the first electrode layer 11 on the light incident side. Examples of the kind of transparent substrate include a glass substrate, a resin substrate, and a ceramic substrate.

(First Electrode Layer)

The first electrode layer 11 is preferably a transparent electrode formed of a conductive material that is substantially transparent with respect to the wavelength of the target light to be detected by the photodetector element. It is noted that in the present invention, the description of “substantially transparent” means that the light transmittance is 50% or more, preferably 60% or more, and particularly preferably 80% or more. Examples of the material of the first electrode layer 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the first electrode layer 11 is not particularly limited, and it is preferably 0.01 to 100 μm, more preferably 0.01 to 10 μm, and particularly preferably 0.01 to 1 μm. It is noted that in the present invention, the film thickness of each layer can be measured by observing the cross section of the photodetector element 1 using a scanning electron microscope (SEM) or the like.

(Electron Transport Layer)

As illustrated in FIG. 1, the electron transport layer 21 is provided between the first electrode layer 11 and the photoelectric conversion layer 13. The electron transport layer 21 is a layer having a function of transporting electrons generated in the photoelectric conversion layer 13 to the electrode layer. The electron transport layer is also called a hole block layer. The electron transport layer is formed of an electron transport material capable of exhibiting this function. Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport layer may be a single-layer film or a laminated film having two or more layers. The thickness of the electron transport layer is preferably 10 to 1,000 nm. The upper limit thereof is preferably 800 nm or less. The lower limit thereof is preferably 20 nm or more and more preferably 50 nm or more. In addition, the thickness of the electron transport layer is preferably 0.05 to 10 times, more preferably 0.1 to 5 times, and still more preferably 0.2 to 2 times the thickness of the photoelectric conversion layer 13.

(Photoelectric Conversion Layer)

The photoelectric conversion layer 13 contains an aggregate of semiconductor quantum dots that contain a metal atom, and it contains a ligand that is coordinated to the semiconductor quantum dot. That is, the photoelectric conversion layer 13 is composed of a semiconductor film containing an aggregate of semiconductor quantum dots that contain a metal atom and containing a ligand that is coordinated to the semiconductor quantum dot. The aggregate of semiconductor quantum dots means a form in which a large number of semiconductor quantum dots (for example, 100 or more quantum dots per 1 μm²) are arranged close to each other. In addition, the “semiconductor” in the present invention means a substance having a specific resistance value of 10⁻² Ωcm or more and 10⁸ Ωcm or less.

The semiconductor quantum dot is a semiconductor particle having a metal atom. It is noted that in the present invention, the metal atom also includes a metalloid atom represented by a Si atom. Examples of the semiconductor quantum dot material that constitutes the semiconductor quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element].

The semiconductor quantum dot preferably contains at least one metal atom selected from a Pb atom, an In atom, a Ge atom, a Si atom, a Cd atom, a Zn atom, a Hg atom, an Al atom, a Sn atom, or a Ga atom, more preferably at least one metal atom selected from a Pb atom, an In atom, a Ge atom, or a Si atom, and due to the reason that the effects of the present invention are easily obtained more remarkably, it still more preferably contains a Pb atom.

Specific examples of the semiconductor quantum dot material that constitutes the semiconductor quantum dot include semiconductor materials having a relatively narrow band gap, such as PbS, Pb Se, PbTe, InN, InAs, Ge, InGaAs, CuInS, CuInSe, CuInGaSe, InSb, HgTe, HgCdTe, Ag₂S, Ag₂Se, Ag₂Te, SnS, SnSe, SnTe, Si, and InP. Among them, the semiconductor quantum dot preferably contains PbS or Pb Se, and more preferably contains PbS, due to the reason that it is easy to efficiently convert light in the infrared region (preferably, light having a wavelength of 700 to 2,500 nm) to electrons.

The semiconductor quantum dot may be a material having a core-shell structure in which a semiconductor quantum dot material is made to the nucleus (the core) and the semiconductor quantum dot material is covered with a coating compound. Examples of the coating compound include ZnS, ZnSe, ZnTe, ZnCdS, CdS, and GaP.

The band gap Eg1 of the semiconductor quantum dot is preferably 0.5 to 2.0 eV. In a case where the band gap Eg1 of the semiconductor quantum dot is within the above range, it is possible to obtain a photodetector element capable of detecting light of various wavelengths depending on the use application. For example, it is possible to obtain a photodetector element capable of detecting light in the infrared region. The upper limit of the band gap Eg1 of the semiconductor quantum dot is preferably 1.9 eV or less, more preferably 1.8 eV or less, and still more preferably 1.5 eV or less. The lower limit of the band gap Eg1 of the semiconductor quantum dot is preferably 0.6 eV or more and more preferably 0.7 eV or more.

The average particle diameter of the semiconductor quantum dots is preferably 2 nm to 15 nm. The average particle diameter of the semiconductor quantum dots is an average value of the particle diameters of ten semiconductor quantum dots which are randomly selected. A transmission electron microscope may be used for measuring the particle diameter of the semiconductor quantum dots.

Generally, a semiconductor quantum dot contains particles of various sizes from several nm to several tens of nm. In a case where the average particle diameter of semiconductor quantum dots is reduced to a size equal to or smaller than the Bohr radius of the electrons present in the inside of the semiconductor quantum dot, a phenomenon in which the band gap of the semiconductor quantum dot changes due to the quantum size effect occurs. In a case where the average particle diameter of semiconductor quantum dots is 15 nm or less, it is easy to control the band gap by the quantum size effect.

The photoelectric conversion layer 13 of the photodetector element according to the embodiment of the present invention contains a ligand that is coordinated to the semiconductor quantum dot. Examples of the ligand include a ligand containing a halogen atom and a polydentate ligand containing two or more coordination moieties. The photoelectric conversion layer 13 may contain only one kind of ligand or may contain two or more kinds of ligands. Among the above, the photoelectric conversion layer 13 preferably contains a ligand containing a halogen atom and a polydentate ligand. According to this aspect, it is possible for the photodetector element to have a low dark current and have excellent performance such as electrical conductivity, a photocurrent value, an external quantum efficiency, and an in-plane uniformity of external quantum efficiency. It is presumed that the reason why such effects are obtained is as follows. It is presumed that the polydentate ligand is subjected to chelate coordination to the semiconductor quantum dot, and thus it is presumed that the peeling of the ligand from the semiconductor quantum dot can be suppressed more effectively. In addition, it is presumed that steric hindrance between semiconductor quantum dots can be suppressed by chelate coordination. For this reason, it is conceived that the steric hindrance between the semiconductor quantum dots is reduced, and thus the semiconductor quantum dots are closely arranged to strengthen the overlap of the wave functions between the semiconductor quantum dots. Furthermore, in a case where a ligand containing a halogen atom is further contained as the ligand that is coordinated to the semiconductor quantum dot, it is presumed that the ligand containing a halogen atom is coordinated in the gap where the polydentate ligand is not coordinated, and thus it is presumed that the surface defects of the semiconductor quantum dot can be reduced. As a result, it is presumed that it is possible for the photodetector element to have a low dark current and have excellent performance such as electrical conductivity, a photocurrent value, an external quantum efficiency, and an in-plane uniformity of external quantum efficiency.

First, the ligand containing a halogen atom will be described. Examples of the halogen atom contained in the ligand include a fluorine atom, a chlorine atom, a bromine atom, and an iodine atom, and an iodine atom is preferable from the viewpoint of coordinating power.

The ligand containing a halogen atom may be an organic halide or may be an inorganic halide. Among the above, an inorganic halide is preferable due to the reason that it is easily coordinated to both the cation site and the anion site of the semiconductor quantum dot. In addition, the inorganic halide is preferably a compound containing a metal atom selected from a Zn atom, an In atom, and a Cd atom, and it is more preferably a compound containing a Zn atom. The inorganic halide is preferably a salt of a metal atom and a halogen atom due to the reason that the salt is ionized and easily coordinated to the semiconductor quantum dot.

Specific examples of the ligand containing a halogen atom include zinc iodide, zinc bromide, zinc chloride, indium iodide, indium bromide, indium chloride, cadmium iodide, cadmium bromide, and cadmium chloride, gallium iodide, gallium bromide, gallium chloride, tetrabutylammonium iodide, and tetramethylammonium iodide, and zinc iodide is particularly preferable.

In the ligand containing a halogen atom, the halogen ion may be dissociated from the ligand containing a halogen atom, and the halogen ion may be coordinated on the surface of the semiconductor quantum dot. In addition, a portion of the ligand containing a halogen atom, other than the halogen, may also be coordinated on the surface of the semiconductor quantum dot. To give a description with a specific example, in the case of zinc iodide, zinc iodide may be coordinated on the surface of the semiconductor quantum dot, or the iodine ion or the zinc ion may be coordinated on the surface of the semiconductor quantum dot.

Next, the polydentate ligand will be described. Examples of the coordination moiety contained in the polydentate ligand include a thiol group, an amino group, a hydroxy group, a carboxy group, a sulfo group, a phospho group, and a phosphonate group. The polydentate ligand is preferably a compound containing a thiol group due to the reason that the compound is easily coordinated firmly on the surface of the semiconductor quantum dot.

Examples of the polydentate ligand include a ligand represented by any of Formulae (D) to (F).

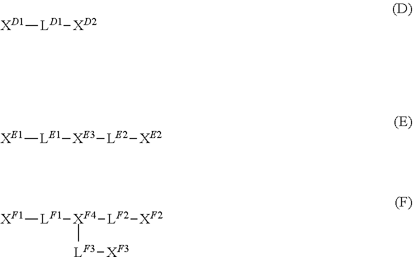

In Formula (D), X^{D1} and X^{D2} each independently represent a thiol group, an amino group, a hydroxy group, a carboxy group, a sulfo group, a phospho group, or a phosphonate group, and

L^{D1} represents a hydrocarbon group.

in Formula (E), X^{E1} and X^{E2} each independently represent a thiol group, an amino group, a hydroxy group, a carboxy group, a sulfo group, a phospho group, or a phosphonate group,

X^{E3} represents S, O, or NH, and

L^{E1} and L^{E2} each independently represent a hydrocarbon group.

in Formula (F), X^{F1} to X^{F3} each independently represent a thiol group, an amino group, a hydroxy group, a carboxy group, a sulfo group, a phospho group, or a phosphonate group,

X^{F4} represents N, and

L^{F1} to L^{F3} each independently represent a hydrocarbon group.

The amino group represented by X^{D1}, X^{D2}, X^{E1}, X^{E2}, X^{F1}, X^{F2}, or X^{F3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{D1}, L^{E1}, L^{E2}, L^{F1}, L^{F2}, or L^{F2} is preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. The upper limit of the number of carbon atoms is preferably 10 or less, more preferably 6 or less, and still more preferably 3 or less. Specific examples of the hydrocarbon group include an alkylene group, an alkenylene group, and an alkynylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. Examples of the alkynylene group include a linear alkynylene group and a branched alkynylene group, and a linear alkynylene group is preferable. The alkylene group, the alkenylene group, and the alkynylene group may further have a substituent. The substituent is preferably a group having 1 or more and 10 or less of carbon atoms. Preferred specific examples of the group having 1 or more and 10 or less of carbon atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (D), X^{D1} and X^{D2} are separated by L^{D1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (E), X^{E1} and X^{E3} are separated by L^{E1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{E2} and X^{E3} are separated by L^{E2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (F), X^{F1} and X^{F4} are separated by L^{F1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{F2} and X^{F4} are separated by L^{F2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{F3} and X^{F4} are separated by L^{F3} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

It is noted that the description that X^{D1} and X^{D2} are separated by L^{D1} by 1 to 10 atoms means that the number of atoms constituting a molecular chain having the shortest distance, connecting X^{D1} and X^{D2}, is 1 to 10 atoms. For example, in a case of Formula (D1), X^{D1} and X^{D2} are separated by two atoms, and in cases of Formulae (D2) and (D3), X^{D1} and X^{D2} are separated by 3 atoms. The numbers added to the following structural formulae represent the arrangement order of atoms constituting a molecular chain having the shortest distance, connecting X^{D1} and X^{D2}.

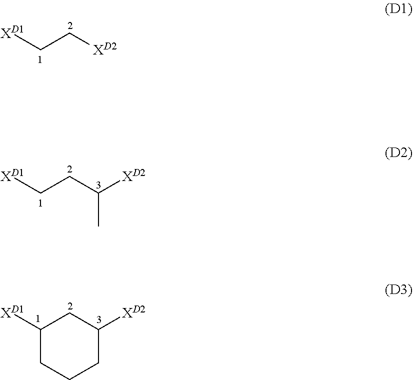

To give a description with a specific compound, 3-mercaptopropionic acid is a compound (a compound having the following structure) having a structure in which a portion corresponding to X^{D1} is a carboxy group, a portion corresponding to X^{D2} is a thiol group, and a portion corresponding to L^{D1} is an ethylene group. In 3-mercaptopropionic acid, X^{D1} (the carboxy group) and X^{D2} (the thiol group) are separated by L^{D1} (the ethylene group) by two atoms.

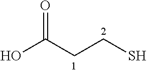

The same applies to the meanings that X^{E1} and X^{E3} are separated by L^{E1} by 1 to 10 atoms, X^{E2} and X^{E3} are separated by L^{E2} by 1 to 10 atoms, X^{F1} and X^{F4} are separated by L^{F1} by 1 to 10 atoms, X^{F2} and X^{F4} are separated by L^{F2} by 1 to 10 atoms, and X^{F3} and X^{F4} are separated by L^{F3} by 1 to 10 atoms.

Specific examples of the polydentate ligand include ethanedithiol, 3-mercaptopropionic acid, thioglycolic acid, 2-aminoethanol, 2-aminoethanethiol, 2-mercaptoethanol, glycolic acid, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propane-1-ol,1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, tartronic acid, and derivatives thereof. Due to the reason that a semiconductor film has a low dark current and a high external quantum efficiency, the polydentate ligand is preferably thioglycolic acid, 2-aminoethanol, 2-aminoethanethiol, 2-mercaptoethanol, glycolic acid, diethylenetriamine, tris(2-aminoethyl)amine, 1-thioglycerol, dimercaprol, ethylenediamine, ethyleneglycol, aminosulfonic acid, glycine, (aminomethyl)phosphonic acid, guanidine, diethanolamine, 2-(2-aminoethyl)aminoethanol, homoserine, cysteine, thiomalic acid, malic acid, or tartaric acid, more preferably thioglycolic acid, 2-aminoethanol, 2-mercaptoethanol, or 2-aminoethanethiol, and still more preferably thioglycolic acid.

The complex stability constant K1 of the polydentate ligand with respect to the metal atom contained in the semiconductor quantum dot is preferably 6 or more, more preferably 8 or more, and still more preferably 9 or more. In a case where the complex stability constant K1 is 6 or more, the strength of the bond between the semiconductor quantum dot and the polydentate ligand can be increased. For this reason, it is possible to suppress the peeling of the polydentate ligand from the semiconductor quantum dot, and as a result, it is possible to improve driving durability.

The complex stability constant K1 is a constant determined by the relationship between a ligand and a metal atom which is a target of the coordinate bond, and it is represented by Expression (b).

Complex stability constant K1=[ML]/([M]×[L]) (b)

In Expression (b), [ML] represents the molar concentration of a complex formed by bonding a metal atom to a ligand, [M] represents the molar concentration of a metal atom contributing to the coordinate bond, and [L] represents the molar concentration of the ligand.

Practically, a plurality of ligands may be coordinated to one metal atom. However, in the present invention, the complex stability constant K1 represented by Expression (b) in a case where one ligand molecule is coordinated to one metal atom is defined as an indicator of the strength of the coordinate bond.

The complex stability constant K1 between the ligand and the metal atom can be determined by spectroscopy, magnetic resonance spectroscopy, potentiometry, solubility measurement, chromatography, calorimetry, solidifying point measurement, vapor pressure measurement, relaxation measurement, viscosity measurement, surface tension measurement, or the like. In the present invention, the complex stability constant K1 is determined using Sc-Database ver. 5.85 (Academic Software) (2010), which summarizes results from various methods and research institutes. In a case where the complex stability constant K1 is not present in the Sc-Database ver. 5.85, a value described in Critical Stability Constants, written by A. E. Martell and R. M. Smith, is used. In a case where the complex stability constant K1 is not described in the Critical Stability Constants, the above-described measurement method is used or a program PKAS method that calculates the complex stability constant K1 (The Determination and Use of Stability Constants, VCH (1988) written by A. E. Martell et. al.) is used to calculate the complex stability constant K1.

In the present invention, a semiconductor quantum dot that contains a Pb atom (more preferably, PbS is used) is used as the semiconductor quantum dot, the complex stability constant K1 of the polydentate ligand with respect to the Pb atom is preferably 6 or more, more preferably 8 or more, and still more preferably 9 or more. Examples of the compound having a complex stability constant K1 of 6 or more with respect to the Pb atom include thioglycolic acid (complex stability constant K1 with respect to Pb=8.5) and 2-mercaptoethanol (complex stability constant K1 with respect to Pb=6.7).

The thickness of the photoelectric conversion layer is preferably 10 to 600 nm, more preferably 50 to 600 nm, still more preferably 100 to 600 nm, and even still more preferably 150 to 600 nm. The upper limit of the thickness is preferably 550 nm or less, more preferably 500 nm or less, and still more preferably 450 nm or less.

The refractive index of the photoelectric conversion layer with respect to light of the target wavelength to be detected by the photodetector element is preferably 2.0 to 3.0, more preferably 2.1 to 2.8, and still more preferably 2.2 to 2.7. According to this aspect, in a case where the configuration of the photodetector element is a photodiode, it is easy to realize a high light absorbance, that is, a high external quantum efficiency.

The photoelectric conversion layer can be formed by undergoing a step (a semiconductor quantum dot aggregate forming step) of applying a semiconductor quantum dot dispersion liquid containing semiconductor quantum dots, a ligand that is coordinated to the semiconductor quantum dot, and a solvent onto a substrate to form a film of aggregate of the semiconductor quantum dots. The method of applying a semiconductor quantum dot dispersion liquid onto a substrate is not particularly limited. Examples thereof include coating methods such as a spin coating method, a dipping method, an ink jet method, a dispenser method, a screen printing method, a relief printing method, an intaglio printing method, and a spray coating method.

In addition, after forming a film of aggregate of the semiconductor quantum dots, a ligand exchange step may be further carried out to exchange the ligand coordinated to the semiconductor quantum dot with another ligand. In the ligand exchange step, a ligand solution containing a ligand A and a solvent is applied onto the film of aggregate of the semiconductor quantum dots, formed by the semiconductor quantum dot aggregate forming step, to exchange the ligand coordinated to the semiconductor quantum dot with the ligand A. The ligand A may contain two or more kinds of ligands, and two kinds of ligand solutions may be used in combination.

On the other hand, a desired ligand may be applied onto the surface of the semiconductor quantum dot in advance, and then, the semiconductor quantum dot dispersion liquid may be applied onto the substrate to form a photoelectric conversion layer.

The content of the semiconductor quantum dot in the semiconductor quantum dot dispersion liquid is preferably 1 to 500 mg/mL, more preferably 10 to 200 mg/mL, and still more preferably 20 to 100 mg/mL.

Examples of the solvent contained in the semiconductor quantum dot dispersion liquid and the ligand solution include an ester-based solvent, a ketone-based solvent, an alcohol-based solvent, an amide-based solvent, an ether-based solvent, and a hydrocarbon-based solvent. For details thereof, paragraph No. 0223 of WO2015/166779A can be referenced, the content of which is incorporated in the present specification. In addition, an ester-based solvent substituted with a cyclic alkyl group and a ketone-based solvent substituted with a cyclic alkyl group can also be used. It is preferable that the solvent has a small amount of metal impurities, and the metal content is, for example, 10 parts per billion (ppb) by mass or less. A solvent of a level of parts per trillion (ppt) by mass may be used as necessary, and such a solvent is provided by, for example, TOAGOSEI Co., Ltd. (The Chemical Daily, Nov. 13, 2015). Examples of the method for removing impurities such as metals from the solvent include distillation (molecular distillation, thin film distillation, and the like) and filtration using a filter. The filter pore diameter of the filter that is used for filtration is preferably 10 μm or less, more preferably 5 μm or less, and still more preferably 3 μm or less. A material of the filter is preferably polytetrafluoroethylene, polyethylene, or nylon. The solvent may contain isomers (compounds having the same number of atoms but having different structures). In addition, only one kind of isomer may be contained, or a plurality of kinds thereof may be contained.

(Hole Transport Layer)

As illustrated in FIG. 1, the hole transport layer 22 is provided between the second electrode layer 12 and the photoelectric conversion layer 13. The hole transport layer is a layer having a function of transporting holes generated in the photoelectric conversion layer to the electrode layer. The hole transport layer is also called an electron block layer. In the photodetector element according to the embodiment of the present invention, it is preferable that the hole transport layer 22 is arranged on the surface of the photoelectric conversion layer 13.

In the photodetector element of the embodiment of the present invention, the hole transport layer 22 contains an organic semiconductor. The hole transport layer 22 is preferably a semiconductor film composed of an organic semiconductor. Examples of the organic semiconductor that constitutes the hole transport layer 22 include a compound represented by any of Formulae 1-1 to 1-6.

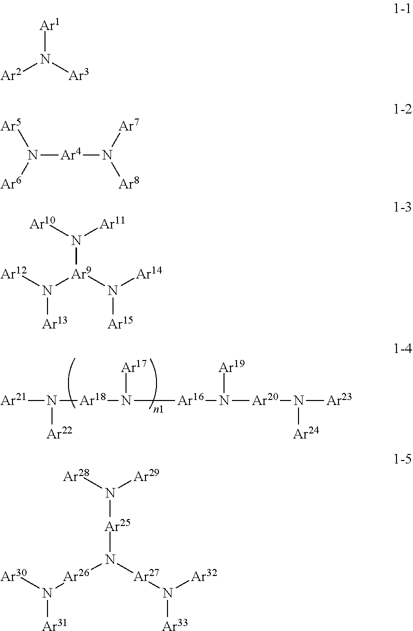

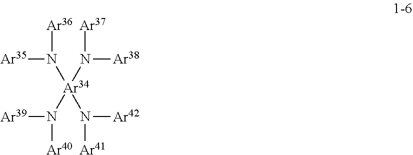

In Formula 1-1, Ar¹ to Ar³ each independently represent an aromatic hydrocarbon group which may have a substituent or an aromatic heterocyclic group which may have a substituent;

in Formula 1-2, Ar⁴ represents a divalent linking group containing an aromatic hydrocarbon group which may have a substituent or an aromatic heterocyclic group which may have a substituent, and Ar⁵ to Ar⁸ each independently represent an aromatic hydrocarbon group which may have a substituent or an aromatic heterocyclic group which may have a substituent;

in Formula 1-3, Ar⁹ to Ar¹⁵ each independently represent an aromatic hydrocarbon group which may have a substituent or an aromatic heterocyclic group which may have a substituent;

in Formula 1-4, Ar¹⁶ to Ar²⁴ each independently represent an aromatic hydrocarbon group which may have a substituent or an aromatic heterocyclic group which may have a substituent, and n1 represents an integer of 0 to 10;

in Formula 1-5, Ar²⁵ to Ar³³ each independently represent an aromatic hydrocarbon group which may have a substituent or an aromatic heterocyclic group which may have a substituent;

in Formula 1-6, Ar³⁴ to Ar⁴² each independently represent an aromatic hydrocarbon group which may have a substituent or an aromatic heterocyclic group which may have a substituent.

The aromatic hydrocarbon group represented by Ar¹ to Ar³ of Formula 1-1, Ar⁵ to Ar⁸ of Formula 1-2, Ar⁹ to Ar¹⁵ of Formula 1-3, Ar¹⁶ to Ar²⁴ of Formula 1-4, Ar²⁵ to Ar³³ of Formula 1-5, and Ar³⁴ to Ar⁴² of Formula 1-6 preferably has 6 to 50 carbon atoms, more preferably 6 to 30 carbon atoms, and still more preferably 6 to 12 carbon atoms. The above aromatic hydrocarbon group may be a monocyclic ring or may be a group obtained by fusing two or more rings. It is preferably a monocyclic ring. Specific examples of the aromatic hydrocarbon group include a benzene ring group, a biphenyl ring group, a triphenyl ring group, a triphenylene ring group, a naphthalene ring group, an anthracene ring group, a phenalene ring group, a phenanthrene ring group, a fluorene ring group, a pyrene ring group, a chrysene ring group, a perylene ring group, and an azulene ring group, where a benzene ring group is preferable.

The number of heteroatoms that constitute a ring of the aromatic heterocyclic group represented by Ar¹ to Ar³ of Formula 1-1, Ar⁵ to Ar⁸ of Formula 1-2, Ar⁹ to Ar¹⁵ of Formula 1-3, Ar¹⁶ to Ar²⁴ of Formula 1-4, Ar²⁵ to Ar³³ of Formula 1-5, or Ar³⁴ to Ar⁴² of Formula 1-6 is preferably 1 to 3. The heteroatom that constitutes a ring of the aromatic heterocyclic group is preferably a nitrogen atom, an oxygen atom, or a sulfur atom. The number of carbon atoms that constitutes a ring of the aromatic heterocyclic group is preferably 1 to 20, more preferably 1 to 15, and still more preferably 1 to 12. The aromatic heterocyclic group may be a monocyclic ring or may be a group obtained by fusing two or more rings. Specific examples of the aromatic heterocyclic group include a dibenzothiophene ring group, a dibenzofuran ring group, a dibenzoselenophene ring group, a furan ring group, a thiophene ring group, a benzofuran ring group, a benzothiophene ring group, a benzoselenophene ring group, a carbazole ring group, an indolocarbazole ring group, a pyridylindole ring group, a pyrrolodipyridine ring group, a pyrazole ring group, an imidazole ring group, a triazole ring group, an oxazole ring group, a thiazole ring group, an oxadiazole ring group, an oxatriazole ring group, an dioxazole ring group, a thiadiazole ring group, a pyridine ring group, a pyridazine ring group, a pyrimidine ring group, a pyrazine ring group, a triazine ring group, an oxazine ring group, an oxathiazine ring group, an oxadiazine ring group, an indole ring group, a benzimidazole ring group, an indazole ring group, an indoxazine ring group, a benzoxazole ring group, a benzisoxazole ring group, a benzothiazole ring group, a quinoline ring group, an isoquinoline ring group, a cinnoline ring group, a quinazoline ring group, a quinoxaline ring group, a naphthylidine ring group, a phthalazine ring group, a pteridine ring group, a xanthene ring group, an acridine ring group, a phenazine ring group, a phenothiazine ring group, a phenoxazine ring group, a benzofuropyridine ring group, a furodipyridine ring group, a benzothienopyridine ring group, a thienodipyridine ring group, a benzoselenophenopyridine ring group, and a selenophenodipyridine ring group.

Ar⁴ of Formula 1-2 represents a divalent linking group including an aromatic hydrocarbon group which may have a substituent or an aromatic heterocyclic group which may have a substituent. Examples of the divalent linking group represented by Ar⁴ include an aromatic hydrocarbon group, an aromatic heterocyclic group, and a group represented by Formula X-1. Examples of the aromatic hydrocarbon group and the aromatic heterocyclic group include the above-described groups.

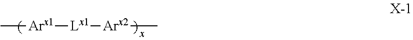

In Formula X-1, Ar^{X1} and Ar^{X2} each independently represent an aromatic hydrocarbon group which may independently have a substituent or an aromatic heterocyclic group which may have a substituent, L^{X1} represents a single bond, a hydrocarbon group, or a group containing at least one atom selected from an oxygen atom, a nitrogen atom, a sulfur atom, a silicon atom, a phosphorus atom, or a boron atom, and X represents an integer of 1 to 10.

L^{X1} is preferably a single bond or a hydrocarbon group, more preferably a hydrocarbon group, and still more preferably an aliphatic hydrocarbon group.

L^{X1} is preferably a group represented by —CR^{X1}CR^{X2}—. R^{X1} and R^{X2} each independently represent an alkyl group, and R^{X1} and R^{X2} may be bonded to each other to form a ring. It is preferable that R^{X1} is bonded to R^{X2} to form a ring. The ring to be formed is preferably a 5-membered or 6-membered aliphatic ring. Preferred specific examples of L^{X1} include the groups shown below. R^{X3} represents a substituent, X1 represents an integer of 0 to 4, and * is a bonding site. Examples of the substituent represented by R^{X3} include substituents which may be contained in the groups represented by Ar¹ to Ar⁴² described later.

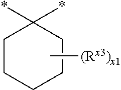

n1 of Formula 1-4 represents an integer of 0 to 10, and it is preferably an integer of 0 to 5, more preferably 0 to 3, and still more preferably 0 or 1.

Examples of the substituent which may be contained in the groups represented by Ar¹ to Ar⁴² include a heavy hydrogen, an alkyl group, an alkenyl group, an alkynyl group, an aryl group, a heterocyclic group, an alkoxy group, an aryloxy group, an alkylthio group, an amino group, an acyl group, an alkoxycarbonyl group, an aryloxycarbonyl group, an acylamino group, a sulfonamide group, a carbamoyl group, a sulfamoyl group, a halogen atom, a nitrile group, an isonitrile group, a hydroxy group, an alkylsulfinyl group, an arylsulfinyl group, an alkylsulfonyl group, an arylsulfonyl group, a phosphino group, a silyl group, and a carboxy group.

The alkyl group preferably has 1 to 20 carbon atoms, more preferably 1 to 15 carbon atoms, and still more preferably 1 to 10 carbon atoms. The alkyl group may be linear, branched, or cyclic.

The alkenyl group preferably has 2 to 20 carbon atoms, more preferably 2 to 15 carbon atoms, and still more preferably 2 to 10 carbon atoms. The alkenyl group may be linear, branched, or cyclic.

The alkynyl group preferably has 2 to 20 carbon atoms, more preferably 2 to 15 carbon atoms, and still more preferably 2 to 10 carbon atoms. The alkynyl group may be linear or branched.

The aryl group preferably has 6 to 50 carbon atoms, more preferably 6 to 30 carbon atoms, and still more preferably 6 to 12 carbon atoms. The aryl group may be a monocyclic ring or may be a group obtained by fusing two or more rings.

The number of heteroatoms that constitute a ring of the heterocyclic group is preferably 1 to 3. The heteroatom that constitutes a ring of the heterocyclic group is preferably a nitrogen atom, an oxygen atom, or a sulfur atom. The number of carbon atoms that constitutes a ring of the heterocyclic group is preferably 1 to 20, more preferably 1 to 15, and still more preferably 1 to 12. The heterocyclic group may be a monocyclic ring or may be a group obtained by fusing two or more rings. The heterocyclic group may be a non-aromatic heterocyclic ring or may be an aromatic heterocyclic ring.

The alkoxy group preferably has 1 to 20 carbon atoms, more preferably 1 to 15 carbon atoms, and still more preferably 1 to 10 carbon atoms. The alkoxy group may be linear or branched.

The aryloxy group preferably has 6 to 50 carbon atoms, more preferably 6 to 30 carbon atoms, and still more preferably 6 to 12 carbon atoms. The aryl moiety of the aryloxy group may be a monocyclic ring or may be a group obtained by fusing two or more rings.

The alkylthio group preferably has 1 to 20 carbon atoms, more preferably 1 to 15 carbon atoms, and still more preferably 1 to 10 carbon atoms. The alkylthio group may be linear or branched.

The amino group is preferably —NH₂, a monoalkylamino or dialkylamino group, a monoarylamino group, or an alkylarylamino group. The alkyl group in the monoalkylamino or dialkylamino group or the alkylarylamino group preferably has 1 to 20 carbon atoms, more preferably 1 to 15 carbon atoms, and still more preferably 1 to 10 carbon atoms. The alkyl group may be linear, branched, or cyclic. The aryl group in the monoarylamino or diarylamino group or the alkylarylamino group preferably has 6 to 50 carbon atoms, more preferably 6 to 30 carbon atoms, and still more preferably 6 to 12 carbon atoms. The aryl group may be a monocyclic ring or may be a group obtained by fusing two or more rings.

The acyl group preferably has 2 to 50 carbon atoms, more preferably 2 to 30 carbon atoms, and still more preferably 2 to 12 carbon atoms.

The alkoxycarbonyl group preferably has 2 to 20 carbon atoms, more preferably 2 to 15 carbon atoms, and still more preferably 2 to 10 carbon atoms. The alkoxycarbonyl group may be linear or branched.

The aryloxycarbonyl group preferably has 7 to 50 carbon atoms, more preferably 7 to 30 carbon atoms, and still more preferably 7 to 12 carbon atoms. The aryl moiety of the aryloxycarbonyl group may be a monocyclic ring or may be a group obtained by fusing two or more rings.

The acylamino group preferably has 2 to 50 carbon atoms, more preferably 2 to 30 carbon atoms, and still more preferably 2 to 12 carbon atoms.

The sulfonamide group preferably has 1 to 50 carbon atoms, more preferably 1 to 30 carbon atoms, and still more preferably 1 to 12 carbon atoms.

The carbamoyl group preferably has 1 to 50 carbon atoms, more preferably 1 to 30 carbon atoms, and still more preferably 1 to 12 carbon atoms.

The sulfamoyl group preferably has 1 to 50 carbon atoms, more preferably 1 to 30 carbon atoms, and still more preferably 1 to 12 carbon atoms.

Examples of the halogen atom include a chlorine atom, a bromine atom, an iodine atom, and a fluorine atom.

The alkylsulfinyl group preferably has 1 to 20 carbon atoms, more preferably 1 to 15 carbon atoms, and still more preferably 1 to 10 carbon atoms.

The arylsulfinyl group preferably has 6 to 50 carbon atoms, more preferably 6 to 30 carbon atoms, and still more preferably 6 to 12 carbon atoms.

The alkylsulfonyl group preferably has 1 to 20 carbon atoms, more preferably 1 to 15 carbon atoms, and still more preferably 1 to 10 carbon atoms.

The arylsulfonyl group preferably has 6 to 50 carbon atoms, more preferably 6 to 30 carbon atoms, and still more preferably 6 to 12 carbon atoms.

The phosphino group preferably has 0 to 30 carbon atoms. Specific examples of the phosphino group include a dimethylphosphino group, a diphenylphosphino group, and a methylphenoxyphosphino group.

The silyl group is preferably a group represented by —SiR^{si1}R^{si2}R^{si3}. R^{si1} to R^{si3} each independently represent an alkyl group or an aryl group, and they are preferably an alkyl group. The alkyl group preferably has 1 to 10 carbon atoms, more preferably 1 to 5 carbon atoms, and still more preferably 1 to 3 carbon atoms. The alkyl group may be linear, branched, or cyclic, and it is preferably linear or branched and more preferably linear. The aryl group preferably has 6 to 50 carbon atoms, more preferably 6 to 30 carbon atoms, and still more preferably 6 to 12 carbon atoms. The aryl group may be a monocyclic ring or may be a group obtained by fusing two or more rings. Specific examples of the silyl group include a trimethylsilyl group, a t-butyldimethylsilyl group, and a phenyldimethylsilyl group.

The substituent which may be contained in the groups represented by Ar¹ to Ar⁴² is preferably an electron donating group. That is, it is preferable that at least one of Ar¹ to Ar³ of Formula 1-1 has an electron donating group, at least one of Ar⁴ to Ar⁸ of Formula 1-2 has an electron donating group, at least one of Ar⁹ to Ar¹⁵ of Formula 1-3 has an electron donating group, at least one of Ar¹⁶ to Ar²⁴ of Formula 1-4 has an electron donating group, at least one of Ar²⁵ to Ar³³ of Formula 1-5 has an electron donating group, and at least one of Ar³⁴ to Ar⁴² of Formula 1-6 has an electron donating group. In a case where the groups represented by Ar¹ to Ar⁴² have an electron donating group as a substituent, the energy level becomes shallower, and thus the blocking effect is improved and the dark current can be expected to be reduced.

Here, the electron donating group is an atomic group that donates an electron to a substituted atomic group in the organic electron theory by an inductive effect or a resonance effect. Examples of the electron donating group include a group having a negative value as the substituent constant (σp (para)) of Hammett's law. The substituent constant (σp (para)) of Hammett's law can be quoted from the 5th edition of the Basics of Chemistry Handbook (page 380 of II). Specific examples of the electron donating group include an alkyl group, an alkenyl group, an alkynyl group, an aryl group, a heterocyclic group, an alkoxy group, an aryloxy group, an alkylthio group, an amino group, a hydroxy group, and a silyl group. The electron donating group is preferably an alkyl group, an alkoxy group, an aryloxy group, an alkylthio group, an amino group, or a silyl group, and due to the reason that the above-described effect can be obtained more remarkably, it is more preferably a tertiary alkyl group or a silyl group.

The organic semiconductor contained in the hole transport layer 22 is preferably a compound represented by Formula 3-1 or Formula 3-2. According to this aspect, it is possible to obtain a photodetector element in which the external quantum efficiency is higher and the dark current is still further reduced.

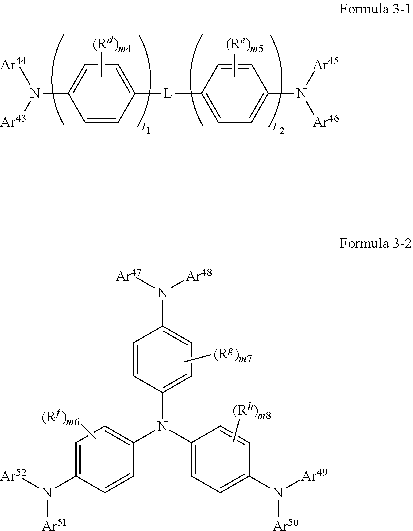

in Formula 3-1, Ar⁴³ to Ar⁴⁶ each independently represent an aromatic heterocyclic group which may have a substituent, a group represented by Formula 3-a, or a group represented by Formula 3-b,

R^{d} and R^{e} each independently represent a substituent,

m⁴ and m⁵ each independently represent an integer of 0 to 4,

I₁ and I₂ each independently represent 1 or 2, and

L represents a single bond or a divalent linking group;

in Formula 3-2, Ar⁴⁷ to Ar⁵² each independently represent an aromatic heterocyclic group which may have a substituent, a group represented by Formula 3-a, or a group represented by Formula 3-b,

R^{f} to R^{h} each independently represent a substituent, and

m6 to m8 each independently represent an integer of 0 to 4;

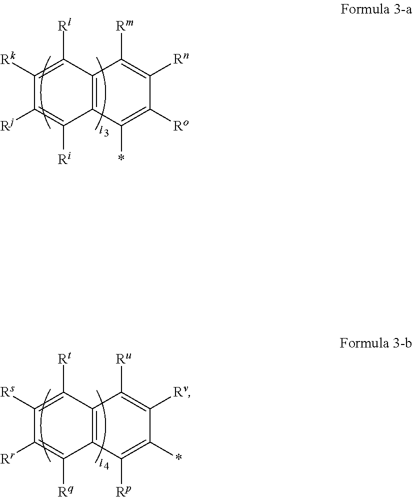

in Formula 3-a, Rⁱ to R^{o} each independently represent a hydrogen atom or a substituent, I₃ represents 0 or 1, and * represents a bonding site;

in Formula 3-b, R^{p} to R^{v} each independently represent a hydrogen atom or a substituent, I₄ represents 0 or 1, and * represents a bonding site.

The aromatic heterocyclic groups represented by Ar⁴³ to Ar⁴⁶ of Formula 3-1 and the aromatic heterocyclic groups represented by Ar⁴⁷ to Ar⁵² have the same meanings as the aromatic heterocyclic groups represented by Ar¹ to Ar³ of Formula 1-1, Ar⁵ to Ar⁸ of Formula 1-2, Ar⁹ to Ar¹⁵ of Formula 1-3, Ar¹⁶ to Ar²⁴ of Formula 1-4, Ar²⁵ to Ar³³ of Formula 1-5, or Ar³⁴ to Ar⁴² of Formula 1-6, and the same applies to the preferred range thereof.

Examples of the substituent which may be contained in the aromatic heterocyclic groups represented by Ar⁴³ to Ar⁴⁶ of Formula 3-1, the substituent which may be contained in the aromatic heterocyclic groups represented by Ar⁴⁷ to Ar⁵² of Formula 3-2, the substituents represented by R^{d} and R^{e} of Formula 3-1, the substituents represented by R^{f} to R^{h} of Formula 3-2, the substituents represented by Rⁱ to R^{o} of Formula 3-a, and the substituents represented by R^{p} to R^{v} of Formula 3-b include the substituents described as the substituent which may be contained in the groups represented by Ar¹ to Ar⁴². They are preferably an electron donating group, more preferably an alkyl group, an alkenyl group, an alkynyl group, an aryl group, a heterocyclic group, an alkoxy group, an aryloxy group, an alkylthio group, an amino group, a hydroxy group, or a silyl group, still more preferably an alkyl group, an alkoxy group, an aryloxy group, an alkylthio group, an amino group, or a silyl group, and due to the reason that the above-described effect can be obtained more remarkably, they are particularly preferably a tertiary alkyl group or a silyl group.

I₁ and I₂ of Formula 3-1 each independently represent 1 or 2, and they are preferably 1.

In Formula (3-1), L represents a single bond or a divalent linking group, and it is preferably a divalent linking group. Examples of the divalent linking group include a hydrocarbon group and a group containing at least one atom selected from an oxygen atom, a nitrogen atom, a sulfur atom, a silicon atom, a phosphorus atom, or a boron atom.

The divalent linking group represented by L is preferably a hydrocarbon group and more preferably a group represented by —CR^{X1}CR^{X2}—. R^{X1} and R^{X2} each independently represent an alkyl group, and R^{X1} and R^{X2} may be bonded to each other to form a ring. It is preferable that R^{X1} is bonded to R^{X2} to form a ring. The ring to be formed is preferably a 5-membered or 6-membered aliphatic ring. Preferred specific examples of the divalent linking group represented by L include the groups shown below. R^{X3} represents a substituent, X1 represents an integer of 0 to 4, and * is a bonding site. Examples of the substituent represented by R^{X3} include the substituent which may be contained in the groups represented by Ar¹ to Ar⁴² described above.

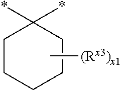

m4 and m5 of Formula 3-1 each independently represent an integer of 0 to 4, and they are preferably 0 to 3, more preferably 0 to 2, still more preferably 0 or 1, and particularly preferably 0. m6 to m8 of Formula 3-2 each independently represent an integer of 0 to 4, and they are preferably 0 to 3, more preferably 0 to 2, still more preferably 0 or 1, and particularly preferably 0.

I₃ of Formula 3-a represents 0 or 1, and it is preferably 0. I₄ of Formula 3-b represents 0 or 1, and it is preferably 0.

In Formula 3-1, Ar⁴³ to Ar⁴⁶ are preferably a group represented by Formula 3-b. In addition, in Formula 3-2, Ar⁴⁷ to Ar⁵² are preferably a group represented by Formula 3-b.

In the group represented by Formula 3-b, it is preferable that I₄ is 0 and R^{s} is an electron donating group, and R^{s} is more preferably an alkyl group, an alkenyl group, an alkynyl group, an aryl group, a heterocyclic group, an alkoxy group, an aryloxy group, an alkylthio group, an amino group, a hydroxy group, or a silyl group, still more preferably an alkyl group, an alkoxy group, an aryloxy group, an alkylthio group, an amino group, or a silyl group, and particularly preferably a tertiary alkyl group or a silyl group.

Further, in the group represented by Formula 3-b, it is also preferable that I₄ is 0 and R^{s}, R^{u}, and R^{p} are each independently a substituent, it is also preferable that R^{s}, R^{u}, and R^{p} are each independently an electron donating group, it also preferable that R^{s}, R^{u}, and R^{p} are each independently an alkyl group, an alkenyl group, an alkynyl group, an aryl group, a heterocyclic group, an alkoxy group, an aryloxy group, an alkylthio group, an amino group, a hydroxy group, or a silyl group, where they are still more preferably an alkyl group, an alkoxy group, an aryloxy group, an alkylthio group, an amino group, or a silyl group, and particularly preferably a methyl group.

Specific examples of the organic semiconductor that is used in the hole transport layer 22 include compounds having the following structures and the compounds described in paragraph No. 0116 of JP2019-163239A.

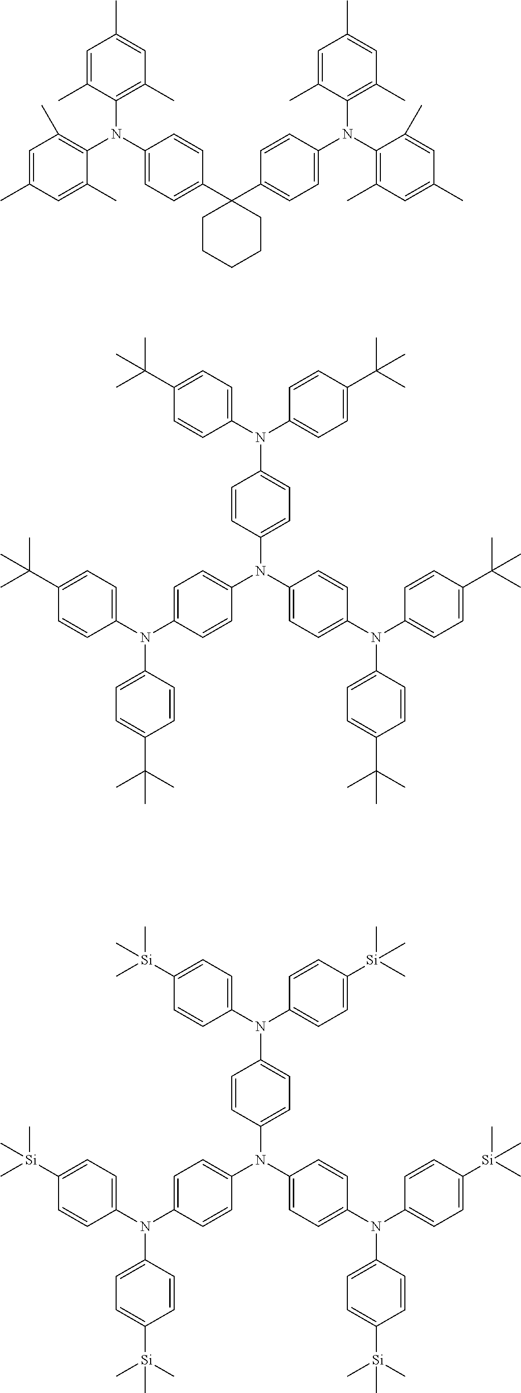

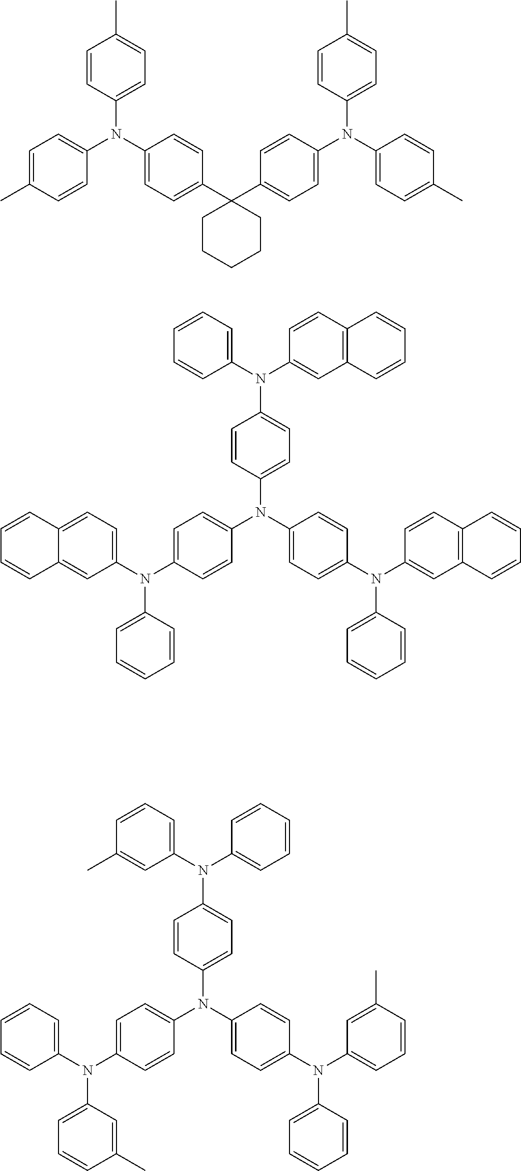

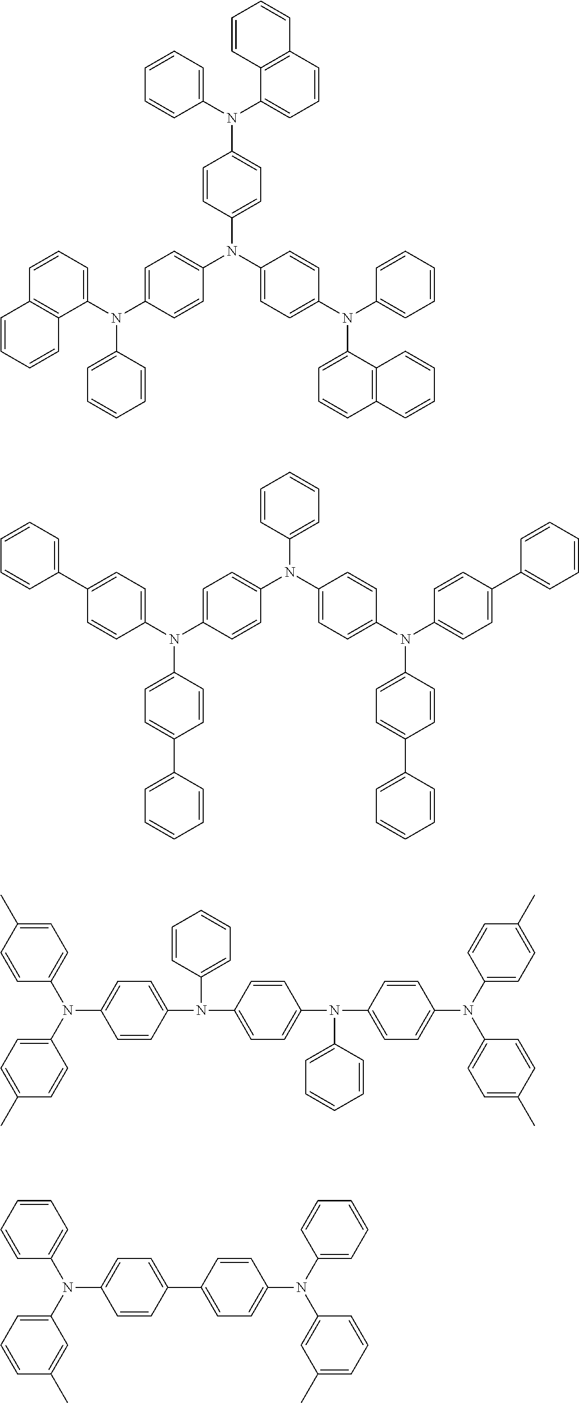 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(N(c4ccccc4)c4ccc(N(c5ccc(-c6ccccc6)cc5)c5ccc(-c6ccccc6)cc5)cc4)cc3)cc2)cc1 ; Cc1ccc(N(c2ccc(C)cc2)c2ccc(N(c3ccccc3)c3ccc(N(c4ccccc4)c4ccc(N(c5ccc(C)cc5)c5ccc(C)cc5)cc4)cc3)cc2)cc1 ; Cc1cccc(N(c2ccccc2)c2ccc(-c3ccc(N(c4ccccc4)c4cccc(C)c4)cc3)cc2)c1]

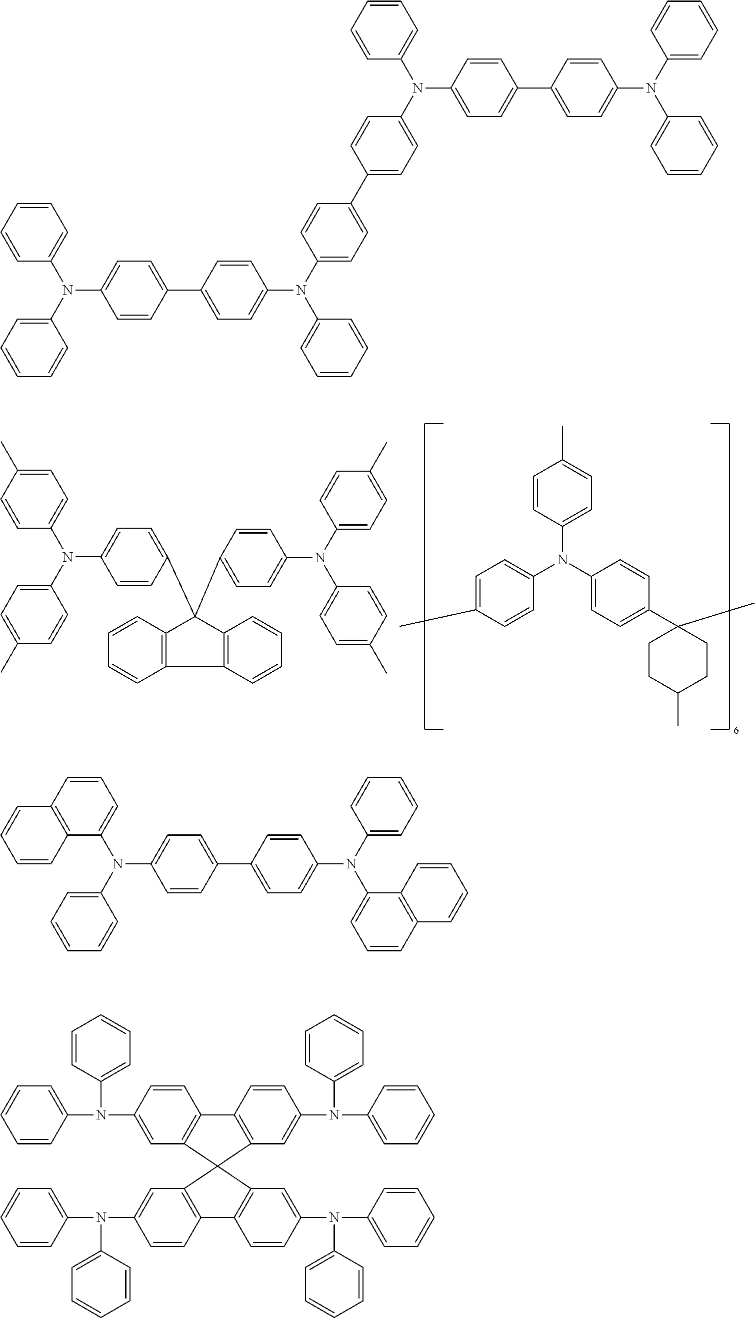

The photodetector element according to the embodiment of the present invention may further have another hole transport layer composed of a hole transport material different from the organic semiconductor. Examples of the hole transport material that constitutes the other hole transport layer include poly(3,4-ethylenedioxythiophene):poly(4-styrenesulfonic acid) (PEDOT:PSS) and MoO₃. In addition, the organic hole transport material disclosed in paragraph Nos. 0209 to 0212 of JP2001-291534A can also be used. In addition, a semiconductor quantum dot can also be used as the hole transport material. Examples of the semiconductor quantum dot material that constitutes the semiconductor quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element]. Specific examples thereof include semiconductor materials having a relatively narrow band gap, such as PbS, PbSe, PbSeS, InN, InAs, Ge, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated on the surface of the semiconductor quantum dot.

In a case where the photodetector element of the embodiment of the present invention includes another hole transport layer, it is preferable that the hole transport layer containing an organic semiconductor is arranged on the photoelectric conversion layer side.

The thickness of the hole transport layer is preferably 5 to 100 nm. The lower limit is preferably 10 nm or more. The upper limit is preferably 50 nm or less and more preferably 30 nm or less.

(Second Electrode Layer)

The second electrode layer 12 is composed of a metal material containing at least one metal atom selected from Au, Pt, Ir, Pd, Cu, Pb, Sn, Zn, Ti, W, Mo, Ta, Ge, Ni, Cr, or In. Since the second electrode layer 12 is composed of such a metal material, it is possible to obtain a photodetector element having a high external quantum efficiency and a low dark current.

The second electrode layer 12 is preferably composed of a metal material containing at least one metal atom selected from Au, Cu, Mo, Ni, Pd, W, Ir, Pt, or Ta, and due to the reason that the work function is large and the migration is easily suppressed, it is more preferably composed of a metal material containing at least one metal atom selected from Au, Pd, Ir, or Pt.

In the second electrode layer 12, the content of the Ag atom is preferably 98% by mass or less, more preferably 95% by mass or less, and still more preferably 90% by mass or less. Further, it is also preferable that the second electrode layer 12 contains substantially no Ag atoms. The case where the second electrode layer 12 contains substantially no Ag atoms means that the content of the Ag atom in the second electrode layer 12 is 1% by mass or less, where it is preferable that the content thereof is 0.1% by mass or less, and it is more preferable that the second electrode layer 12 contains substantially no Ag atoms.

The work function of the second electrode layer 12 is preferably 4.6 eV or more, more preferably 4.8 to 5.7 eV, and still more preferably 4.9 to 5.3 eV, due to the reason that the electron blocking property due to the hole transport layer is increased and the holes generated in the element are easily collected.

The film thickness of the second electrode layer 12 is not particularly limited, and it is preferably 0.01 to 100 more preferably 0.01 to 10 and particularly preferably 0.01 to

(Blocking Layer)

Although not illustrated in the drawing, the photodetector element of the embodiment of the present invention may have a blocking layer between the first electrode layer 11 and the electron transport layer 21. The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

(Characteristics of Photodetector Element)

In the photodetector element of the embodiment of the present invention, a wavelength λ of the target light to be detected by the photodetector element and an optical path length L^{λ} of the light having the wavelength λ from the surface of the second electrode layer 12 on the side of the photoelectric conversion layer 13 to the surface of the photoelectric conversion layer 13 on the side of the first electrode layer 11 preferably satisfy the relationship of Expression (1-1), and more preferably satisfy the relationship of Expression (1-2). In a case where the wavelength λ and the optical path length satisfy such a relationship, in the photoelectric conversion layer 13, it is possible to arrange phases of the light (the incidence ray) incident from the side of the first electrode layer 11 and phases of the light (the reflected light) reflected on the surface of the second electrode layer 12, and as a result, the light is intensified by the optical interference effect, whereby it is possible to obtain a higher external quantum efficiency.

0.05+m/2≤L^{λ}/λ≤0.35+m/2 (1-1)

0.10+m/2≤L^{λ}/λ≤0.30+m/2 (1-2)

In the above expressions, λ is the wavelength of the target light to be detected by the photodetector element,

L^{λ} is the optical path length of the light having the wavelength λ from a surface of the second electrode layer 12 on a side of the photoelectric conversion layer 13 to a surface of the photoelectric conversion layer 13 on a side of the first electrode layer 11, and

m is an integer of 0 or more.

m is preferably an integer of 0 to 4, more preferably an integer of 0 to 3, and still more preferably an integer of 0 to 2. According to this aspect, the transport characteristics of charges such as the hole and the electron are good, and thus it is possible to increase the external quantum efficiency of the photodetector element.

Here, the optical path length means the product obtained by multiplying the physical thickness of a substance through which light transmits by the refractive index. To give a description with the photoelectric conversion layer 13 as an example, in a case where the thickness of the photoelectric conversion layer is denoted by d¹ and the refractive index of the photoelectric conversion layer with respect to the wavelength λ¹ is denoted by N¹, the optical path length of the light having a wavelength λ¹ and transmitting through the photoelectric conversion layer 13 is N¹×d¹. In a case where the photoelectric conversion layer 13 or the hole transport layer 22 is composed of two or more laminated films or in a case where an interlayer is present between the hole transport layer 22 and the second electrode layer 12, the integrated value of the optical path length of each layer is the optical path length L^{λ}.

The photodetector element according to the embodiment of the present invention is preferably used as an element that detects light having a wavelength in the infrared region. That is, the photodetector element according to the embodiment of the present invention is preferably an infrared photodetector element. In addition, the target light to be detected by the above-described photodetector element is preferably light having a wavelength in the infrared region. In addition, the light having a wavelength in the infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less, more preferably light having a wavelength of 1,800 nm or less, and still more preferably light having a wavelength of 1,600 nm or less.

In addition, the photodetector element according to the embodiment of the present invention may simultaneously detect light having a wavelength in the infrared region and light having a wavelength in the visible region (preferably light having a wavelength in a range of 400 to 700 nm).

<Image Sensor>

The image sensor according to the embodiment of the present invention includes the above-described photodetector element according to the embodiment of the present invention. The configuration of the image sensor is not particularly limited as long as it has the photodetector element according to the embodiment of the present invention and it is a configuration that functions as an image sensor.

The image sensor according to the embodiment of the present invention may include an infrared transmitting filter layer. The infrared transmitting filter layer preferably has a low light transmittance in the wavelength range of the visible region, more preferably has an average light transmittance of 10% or less, still more preferably 7.5% or less, and particularly preferably 5% or less in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or a coloring material containing a black coloring material. Examples of the combination of the chromatic coloring material in a case of forming a black color by a combination of two or more kinds of chromatic coloring materials include the following aspects (C1) to (C7).

(C1) an aspect containing a red coloring material and a blue coloring material.

(C2) an aspect containing a red coloring material, a blue coloring material, and a yellow coloring material.

(C3) an aspect containing a red coloring material, a blue coloring material, a yellow coloring material, and a purple coloring material.

(C4) an aspect containing a red coloring material, a blue coloring material, a yellow coloring material, a purple coloring material, and a green coloring material.

(C5) an aspect containing a red coloring material, a blue coloring material, a yellow coloring material, and a green coloring material.

(C6) an aspect containing a red coloring material, a blue coloring material, and a green coloring material.

(C7) an aspect containing a yellow coloring material and a purple coloring material.

The chromatic coloring material may be a pigment or a dye. It may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).

(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).

(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).

(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).

(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).

(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, as the infrared transmitting filter, the films disclosed in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. In addition, as the infrared transmitting filter, two or more filters may be used in combination, or a dual bandpass filter that transmits through two or more specific wavelength ranges with one filter may be used.

The image sensor according to the embodiment of the present invention may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor according to the embodiment of the present invention may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of laminated layers of the dielectric thin film in the dielectric multi-layer film is not particularly limited; however, it is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1λ to 0.5λ in a case where the wavelength of the light to be blocked is λ (nm). Specific examples of the dielectric multi-layer film include the dielectric multi-layer films disclosed in JP2014-130344A and JP2018-010296A.

In the dielectric multi-layer film, the transmission wavelength range is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength range is preferably “the central wavelength λₜ₁±100 nm”, more preferably “the central wavelength λₜ₁±75 nm”, and still more preferably “the central wavelength λₜ₁±50 nm”.

The dielectric multi-layer film may have only one transmission wavelength range (preferably, a transmission wavelength range having a maximum transmittance of 90% or more) or may have a plurality of transmission wavelength ranges.

The image sensor according to the embodiment of the present invention may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. As the color separation filter layer, for example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

In a case where the image sensor according to the embodiment of the present invention includes an infrared transmitting filter layer and a color separation layer, it is preferable that the color separation layer is provided on an optical path different from the infrared transmitting filter layer. In addition, it is also preferable that the infrared transmitting filter layer and the color separation layer are arranged two-dimensionally. The fact that the infrared transmitting filter layer and the color separation layer are two-dimensionally arranged means that at least a part of both is present on the same plane.

The image sensor according to the embodiment of the present invention may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

The photodetector element according to the embodiment of the present invention has excellent sensitivity to light having a wavelength in the infrared region. As a result, the image sensor according to the embodiment of the present invention can be preferably used as an infrared image sensor. In addition, the image sensor according to the embodiment of the present invention can be preferably used as a sensor that senses light having a wavelength of 900 to 2,000 nm and can be more preferably used as a sensor that senses light having a wavelength of 900 to 1,600 nm.

### EXAMPLES

Hereinafter, the present invention will be described more specifically with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

<Preparation of Dispersion Liquid of PbS Quantum Dots>

(Dispersion Liquid of PbS Quantum Dots)

1.3 mL of oleic acid, 2 mmol of lead oxide, and 19 mL of octadecene were weighed and taken in a flask and heated at 110° C. under vacuum for 90 minutes to obtain a precursor solution. Then, the temperature of the solution was adjusted to 95° C., and subsequently, the inside of the system was made into a nitrogen flow state. Then, 1 mmol of hexamethyldisilathiane was injected together with 5 mL of octadecene. Immediately after the injection, the flask was naturally cooled, and at the stage where the temperature reached 30° C., 12 mL of hexane was added thereto, and a solution was recovered. An excess amount of ethanol was added to the solution, centrifugation was carried out at 10,000 rpm for 10 minutes, and the precipitate was dispersed in octane, to obtain a PbS quantum dot dispersion liquid having 40 mg/mL of PbS quantum dots. The band gap estimated from the absorption measurement of the PbS quantum dot dispersion liquid was about 1.33 eV.

(Production of Photodetector Element)

### Examples 1 to 4

A titanium oxide film of 20 nm was formed by sputtering on a quartz glass substrate attached with an indium-tin oxide film (a first electrode layer). Next, the above dispersion liquid of PbS quantum dots was added dropwise onto the titanium oxide film formed on the substrate, and spin coating was carried out at 2,500 rpm to form a PbS quantum dot aggregate film (a step 1). Next, as the ligand solution, a methanol solution of 25 mmol/L of zinc iodide and a methanol solution of 0.01% by volume of thioglycolic acid were added dropwise onto the PbS quantum dot aggregate film, subsequently allowed to stand for 10 seconds, and spin drying was carried out at 2,500 rpm for 20 seconds. Next, acetonitrile was added dropwise onto the PbS quantum dot aggregate film, and spin drying was carried out at 2,500 rpm for 20 seconds to carry out the ligand exchange of the ligand coordinated to the PbS quantum dot from oleic acid to thioglycolic acid and zinc iodide (a step 2). The operation of the step 1 and step 2 as one cycle was repeated for 10 cycles, drying was subsequently carried out for 10 hours in a nitrogen atmosphere, and a photoelectric conversion layer, which was the PbS quantum dot aggregate film in which the ligand had been subjected to ligand exchange from oleic acid to thioglycolic acid and zinc iodide, was formed to a thickness of 220 nm.

Next, the organic semiconductor shown in Table 1 was vacuum-deposited so that the film thickness was 80 nm, whereby a hole transport layer was formed.

Next, MoO₃ was vacuum-deposited on the hole transport layer so that the film thickness was 10 nm. Next, Au was vacuum-deposited on the MoO₃ film so that the film thickness was 100 nm, whereby a second electrode layer was formed.

### Comparative Examples 1 to 3

A photodetector element was manufactured by carrying out the same operation as in Example 1, except that the organic semiconductor shown in Table 1 was used and vacuum deposition was carried out so that the film thickness was 80 nm to form a hole transport layer and that Ag was vacuum-deposited so that the film thickness was 100 nm to form a second electrode layer.

TABLE 1

| | Kind of organic | Kind of second |
|---|---|---|
| | semiconductor | electrode layer |
| Example 1 | Compound A | Au |
| Example 2 | Compound B | Au |
| Example 3 | Compound C | Au |
| Example 4 | Compound D | Au |
| Comparative Example 1 | Compound E | Ag |
| Comparative Example 2 | Compound A | Ag |
| Comparative Example 3 | Compound D | Ag |

Compound A: A compound having the following structure 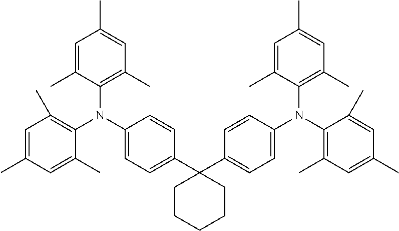
Compound B: A compound having the following structure 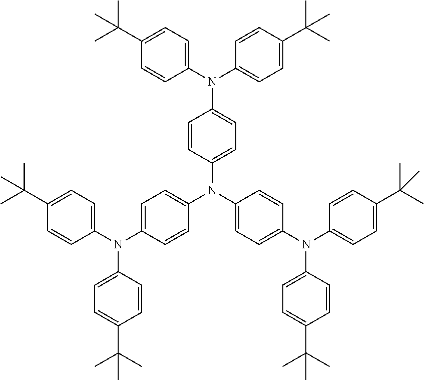 [SMILES: CC(C)(C)c1ccc(N(c2ccc(N(c3ccc(N(c4ccc(C(C)(C)C)cc4)c4ccc(C(C)(C)C)cc4)cc3)c3ccc(N(c4ccc(C(C)(C)C)cc4)c4ccc(C(C)(C)C)cc4)cc3)cc2)c2ccc(C(C)(C)C)cc2)cc1]
Compound C: A compound having the following structure 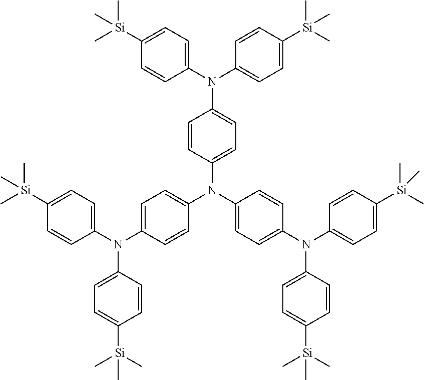
Compound D: A compound having the following structure 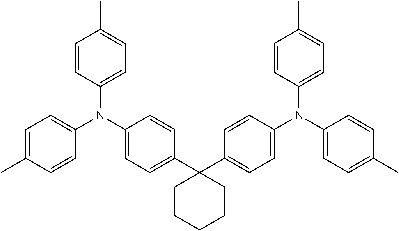
Compound E: A compound having the following structure

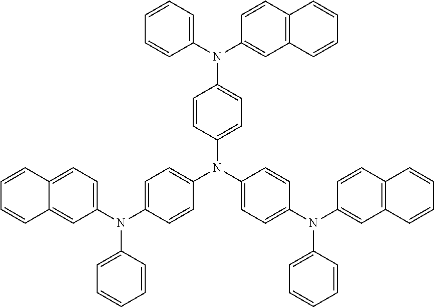 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

<Evaluation of External Quantum Efficiency and Dark Current>

External quantum efficiency (EQE) and dark current were measured for each of the manufactured photodetector elements by using a semiconductor parameter analyzer (C4156, manufactured by Agilent Technologies, Inc.).

First, the current-voltage characteristics (I-V characteristics) were measured while sweeping the voltage from 0 V to −2 V without irradiating light, and the current value at −1 V was evaluated as the dark current.

Subsequently, the I-V characteristics were measured while sweeping the voltage from 0 V to −2 V in a state of carrying out irradiation with monochrome light of 940 nm. The external quantum efficiency (EQE) was calculated from the photocurrent value in a case where −1 V was applied.

TABLE 2

| | External quantum | Dark current |
|---|---|---|
| | efficiency (%) | (A/cm²) |
| Example 1 | 49.3 | 1.4 × 10⁻⁷ |
| Example 2 | 47.8 | 1.2 × 10⁻⁷ |
| Example 3 | 48.9 | 1.6 × 10⁻⁷ |
| Example 4 | 47.5 | 1.9 × 10⁻⁷ |
| Comparative Example 1 | 34.2 | 8.0 × 10⁻⁶ |
| Comparative Example 2 | 36.8 | 3.6 × 10⁻⁶ |
| Comparative Example 3 | 34.1 | 8.6 × 10⁻⁶ |

As shown in Table 2, the photodetector element of Example has a high external quantum efficiency and a low dark current as compared with Comparative Example.

In a case where an image sensor is produced by a known method by using the photodetector element obtained in Example described and incorporating it into a solid-state imaging element together with an optical filter produced according to the methods disclosed in WO2016/186050A and WO2016/190162A, it is possible to obtain an image sensor having good visible and infrared imaging performance.

In each Example, the same effect can be obtained even in a case where the semiconductor quantum dots of the photoelectric conversion layer are changed to PbSe quantum dots.

In each Example, the same effect can be obtained even in a case where the second electrode layer is formed of Pd instead of Au.

### EXPLANATION OF REFERENCES

1: photodetector element
11: first electrode layer
12: second electrode layer
13: photoelectric conversion layer
21: electron transport layer
22: hole transport layer

What is claimed is:

1. A photodetector element comprising:
a first electrode layer;
a second electrode layer;
a photoelectric conversion layer provided between the first electrode layer and the second electrode layer;
an electron transport layer provided between the first electrode layer and the photoelectric conversion layer; and
a hole transport layer provided between the photoelectric conversion layer and the second electrode layer,
wherein the photoelectric conversion layer contains an aggregate of semiconductor quantum dots that contain a metal atom and contains a ligand coordinated to the semiconductor quantum dot,
the hole transport layer contains an organic semiconductor, and
the second electrode layer is formed of a metal material containing at least one metal atom selected from Au, Pt, Ir, Pd, Cu, Pb, Sn, Zn, Ti, W, Mo, Ta, Ge, Ni, Cr, or In.

2. The photodetector element according to claim 1,
wherein a content of an Ag atom in the second electrode layer is 98% by mass or less.

3. The photodetector element according to claim 1,
wherein the second electrode layer is formed of a metal material containing at least one metal atom selected from Au, Pd, Ir, or Pt.

4. The photodetector element according to claim 1,
wherein a work function of the second electrode layer is 4.6 eV or more.

5. The photodetector element according to claim 1,
wherein the organic semiconductor contained in the hole transport layer is a compound represented by any of Formulae 1-1 to 1-6, 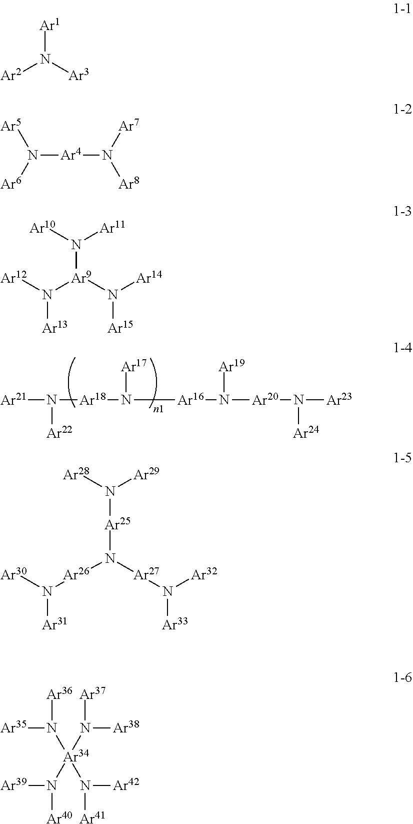
in Formula 1-1, Ar¹ to Ar³ each independently represent an aromatic hydrocarbon group which may have a substituent or an aromatic heterocyclic group which may have a substituent;
in Formula 1-2, Ar⁴ represents a divalent linking group containing an aromatic hydrocarbon group which may have a substituent or an aromatic heterocyclic group which may have a substituent, and Ar⁵ to Ar⁸ each independently represent an aromatic hydrocarbon group which may have a substituent or an aromatic heterocyclic group which may have a substituent;
in Formula 1-3, Ar⁹ to Ar¹⁵ each independently represent an aromatic hydrocarbon group which may have a substituent or an aromatic heterocyclic group which may have a substituent;
in Formula 1-4, Ar¹⁶ to Ar²⁴ each independently represent an aromatic hydrocarbon group which may have a substituent or an aromatic heterocyclic group which may have a substituent, and n1 represents an integer of 0 to 10;
in Formula 1-5, Ar²⁵ to Ar³³ each independently represent an aromatic hydrocarbon group which may have a substituent or an aromatic heterocyclic group which may have a substituent;
in Formula 1-6, Ar³⁴ to Ar⁴² each independently represent an aromatic hydrocarbon group which may have a substituent or an aromatic heterocyclic group which may have a substituent.

6. The photodetector element according to claim 5,
wherein at least one of Ar¹ to Ar³ of Formula 1-1 has an electron donating group,
at least one of Ar⁴ to Ar⁸ of Formula 1-2 has an electron donating group,
at least one of Ar⁹ to Ar¹⁵ of Formula 1-3 has an electron donating group,
at least one of Ar¹⁶ to Ar²⁴ of Formula 1-4 has an electron donating group,
at least one of Ar²⁵ to Ar³³ of Formula 1-5 has an electron donating group, and
at least one of Ar³⁴ to Ar⁴² of Formula 1-6 has an electron donating group.

7. The photodetector element according to claim 6,
wherein the electron donating group is an alkyl group, an alkenyl group, an alkynyl group, an aryl group, a heterocyclic group, an alkoxy group, an aryloxy group, an alkylthio group, an amino group, a hydroxy group, or a silyl group.

8. The photodetector element according to claim 1,
wherein the organic semiconductor contained in the hole transport layer is a compound represented by Formula 3-1 or 3-2, 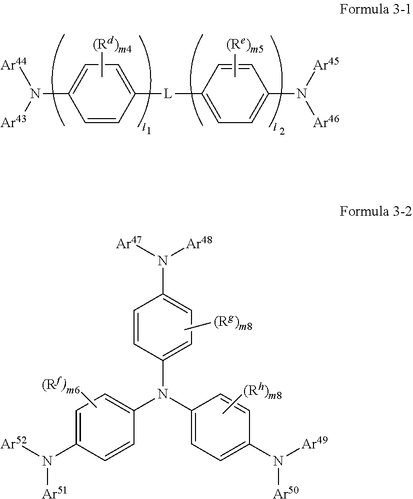
in Formula 3-1, Ar⁴³ to Ar⁴⁶ each independently represent an aromatic heterocyclic group which may have a substituent, a group represented by Formula 3-a, or a group represented by Formula 3-b,
R^{d} and R^{e} each independently represent a substituent,
m⁴ and m⁵ each independently represent an integer of 0 to 4,
I₁ and I₂ each independently represent 1 or 2, and
L represents a single bond or a divalent linking group;
in Formula 3-2, Ar⁴⁷ to Ar⁵² each independently represent an aromatic heterocyclic group which may have a substituent, a group represented by Formula 3-a, or a group represented by Formula 3-b,
R^{f} to R^{h} each independently represent a substituent, and
m6 to m8 each independently represent an integer of 0 to 4; 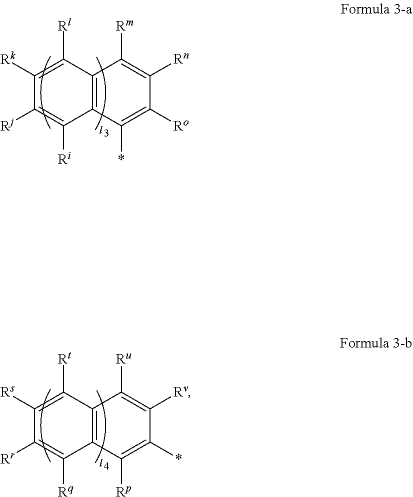
in Formula 3-a, Rⁱ to R^{o} each independently represent a hydrogen atom or a substituent, I₃ represents 0 or 1, and * represents a bonding site;
in Formula 3-b, R^{p} to R^{v} each independently represent a hydrogen atom or a substituent, I₄ represents 0 or 1, and * represents a bonding site.

9. The photodetector element according to claim 8,
wherein at least one of Ar⁴³ to Ar⁴⁶ of Formula 3-1 has an electron donating group, and
at least one of Ar⁴⁷ to Ar⁵² of Formula 3-2 has an electron donating group.

10. The photodetector element according to claim 1,
wherein the semiconductor quantum dot contains a Pb atom.

11. The photodetector element according to claim 1,
wherein the semiconductor quantum dot contains PbS.

12. The photodetector element according to claim 1,
wherein the ligand contains at least one selected from a ligand containing a halogen atom or a polydentate ligand containing two or more coordination moieties.

13. The photodetector element according to claim 12,
wherein the ligand containing a halogen atom is an inorganic halide.

14. The photodetector element according to claim 13,
wherein the inorganic halide contains a Zn atom.

15. The photodetector element according to claim 1,
wherein the photodetector element is a photodiode-type photodetector element.

16. An image sensor comprising the photodetector element according to claim 1.

17. The image sensor according to claim 16,
wherein the image sensor is an infrared image sensor.
